(19) United States
(12) Patent Application Publication
(10) Pub. No.: US 2025/0275053 A1
(43) Pub. Date: Aug. 28, 2025

(54) Electronic control and command assembly and groundskeeping tool provided with said electronic control and command assembly

(71) Applicant: EMAK S.P.A., BAGNOLO IN PIANO (RE) (IT)

(72) Inventors: Gianluca BARBOLINI, MODENA (IT); Umberto VAGLIONI, MODENA (IT)

(21) Appl. No.: 18/855,258

(22) PCT Filed: Apr. 4, 2023
(86) PCT No.: PCT/IB2023/053390

§ 371 Date: Oct. 8, 2024

(30) Foreign Application Priority Data
Apr. 12, 2022 (IT) 102022000007271

(51) Int. Cl. H05K 1/02

(52) U.S. Cl. CPC H05K 1/0203; H05K 2201/10189; H05K 2201/10416

(57) ABSTRACT

A control and command electronic assembly (20,20′) for a groundskeeping tool is described, said control and command electronic assembly comprising a heat sink body (60,60′) and a control and command electronic board (25,25′), said electronic board comprising: a support plate (30,30′) provided with a first major face (35,35′) and an opposite second major face (40,40′), a plurality of electronic components (45,50) fixed to the support plate (30,30′) and comprising at least one electronic component (45), which generates heat that must be dissipated by means of the heat sink body and which has a predetermined height from the major face, between the first and the second, on which it is fixed of the support plate, and a connection body (55) fixed to the support plate (30,30′) and adapted to allow the removable connection to the electronic board (25,25′) of a cable, and/or another electronic component (50) of the plurality of electronic components, which is fixed to the support plate (30,30′) and has a predetermined height from a portion of the plate on which it is fixed that is greater than the predetermined height of the electronic component whose heat is to be dissipated. Wherein the heat sink body comprises a base face (65,65′) facing onto the first major face (35,35′) of the support plate and the connection body (55) and/or the other electronic component (50) is fixed to the second major face (40,40′) of the support plate.

### TECHNICAL FIELD

The present invention relates to an electronic control and command assembly for a groundskeeping tool, such as for example chainsaws, brushcutters, hedge trimmers, blowers, lawnmowers, etc.

### PRIOR ART

Electronic control and command assemblies, also known as control units, are known, for example for controlling a motor of a tool. Said electronic control and command groups are provided with an electronic board comprising a support plate in electrically insulating material and provided with a major face from which a plurality of electronic components rises, such as for example mosfets, power transistors, current diverters, processors, capacitors, resistors and inductors.

Connection bodies, such as connectors and/or terminals, galvanically connected to the electronic components and allowing cables to be fixed to the electronic board for connection to other electrical components of the tool, such as the battery and the motor, are also installed on the same major face. The connectors and the terminals are generally positioned near the edges of the support plate, or in any case on the side of the power electronic components, such as mosfets, power transistors and current diverters, and on the side of the processors, which are generally positioned centrally to the support plate and generate an amount of heat that must be dissipated by appropriate means.

Other electronic components, such as for example capacitors, which have a height from the major face of the support plate greater than the height from the major face of the power components, are also generally located on the side of the power components. The electronic control and command assemblies also comprise a heat sink for dissipating the heat generated by the aforementioned electronic components, generally in the form of an aluminium or copper body fitted with fins, configured to dissipate the heat generated by the electronic board, in particular to dispose of the heat generated by the so-called power electronic components, i.e. mosfets, power transistors and current diverters.

The connectors and the terminals, both for their extension in height with respect to the support plate and for the necessity to have a free volume around them in order to be able to carry out the manoeuvres for fixing or removing the cables, are an obstacle to the dimensions of the heat sink body, in particular they are an obstacle to the extension of a base of said body turned towards the support plate, which is the first portion of the body that is hit by the heat generated by the power components and therefore must be in contact either direct or by means of a thin film of thermally conductive material with a portion of said power electronic components that is distal from the portion fixed to the support plate (it is specified that extension of the base refers to the dimensions of the base along directions lying on a plane parallel to the major face).

Even the aforementioned electronic components that are taller than power components, although they do not require a free space around them for the connection and removal of the cables, are an obstacle to the extension of the base of the heat sink body. Therefore, the current architecture is limiting the capabilities to dissipate the heat generated by electronic components, especially by power components.

Aim of the present invention is to overcome the constraints of the prior art in the context of an efficient, rational and cost-effective solution.

Such aim is achieved by the features of the invention reported in the independent claim. The dependent claims outline preferred and/or particularly advantageous aspects of the invention.

### DISCLOSURE OF THE INVENTION

In particular, the invention makes available an electronic control and command assembly, said electronic control and command assembly comprising a heat sink body and an electronic board, said electronic board comprising:
a support plate provided with a first major face and an opposite second major face,
a plurality of electronic components fixed to the support plate and comprising at least one electronic component, which generates a heat that must be dissipated by the heat sink body and which has a predetermined height from the major face of the support plate, between the first and second, on which it is fixed,
a connection body fixed to the support plate for the removable connection to the electronic board of a cable, and/or another electronic component of the plurality of electronic components (which does not require the heat sink body for heat disposal), which is fixed to the support plate and has a predetermined height from a portion of the plate on which it is fixed which is greater than the predetermined height of the electronic component whose heat is to be dissipated from the heat sink body,
said electronic assembly being characterized in that the heat sink body comprises a base face facing onto the first major face of the support plate and in that the connection body and/or the other electronic component is fixed to the second major face of the support plate.

Thanks to this solution, an electronic control and command assembly is made available, which makes it possible to have either, with the same size of the support plate, heat sinks with larger base faces and therefore a greater dissipation capacity, or which, with the same size of the base face of the heat sink body, makes it possible to obtain electronic boards that are more compact compared to the devices of prior art from the point of view of the extension of the major faces of the support plate. With regard to the first aspect, it is obtained by the invention in that the connection bodies (terminals and/or connectors) and the electronic components that are taller than the component whose heat is to be dissipated (generally a power electronic component or a processor) are no longer an obstacle to the extension of the base face of the heat sink body as is the case instead in the devices of prior art, where the base of the heat sink is instead substantially enclosed by said elements of the electronic board because it must be in contact with the electronic component (or more than one of them) of which it must dispose of the heat. In the devices of the prior art, a lying plane of the base face of the heat sink body intersects at least the connectors or terminals and/or the electronic components that are taller than the power components, such as for example capacitors, while in the invention this lying plane does not intersect any electronic component that generates a heat that must be dissipated with the heat sink and does not intersect any connection body. Consequently, without that constructive constraint the base face can be more extended and therefore a better heat disposal can be achieved. With regard to the second advantage made available by the features of claim 1, the distribution of the electronic components also on the second major face, which generally remains empty, together with the positioning of the connectors or terminals on it, makes it possible to make a better use of the support plate and obtain greater compactness. The greater compactness (along directions lying in a plane parallel to the major faces) of the electronic board allows having fewer constraints on the design of the body of the tool inside which the electronic control and command assembly is housed, which can make the achievement of better tool ergonomics possible.

In one embodiment of the electronic control and command board according to the invention, the electronic component whose heat is to be dissipated by the sink body is fixed to the first major face and is in contact with the base face of the heat sink.

In this way, as well as not having the obstacle of the components that are taller than those whose heat is to be dissipated and of the connection bodies, which makes it possible to use heat sink bodies with larger base faces and therefore better heat dissipation, the characteristics presented also make it possible to realize an electronic board with limited dimensions from the point of view of a plane parallel to the major faces thanks to the distribution of the components on the two major faces. Another aspect of the invention contributes to improving this advantage, according to which the plurality of electronic components only comprises:
a first set of electronic components fixed to the first major face, of which the electronic component whose heat is to be dissipated is a part, and which all have a height from the first face of the support plate equal to or less than the predetermined height of the power electronic component in contact with the base face of the heat sink, and
a second set of electronic components fixed to the second major face of the support plate, all of which have a height from the second major face of the support plate greater than the predetermined height.

In another embodiment of the control and command electronic board according to the invention, all the electronic components of the plurality of electronic components (and the connection body if any, or connection bodies if any) are installed on the second face and the electronic board comprises one or more bridges of thermally conductive material that cross the support plate from the second major face to the first major face and are in contact with the base face of the heat sink body. Thanks to this solution, an electronic board that is simple to manufacture is made available, as all the electronic components are fixed to a single, major face, which at the same time allows to use a heat sink with a highly sized base, and therefore high thermal dissipation power.

Regardless of the embodiment of the electronic control and command board, one aspect of the invention may provide that the base face of the heat sink is totally superimposed on the first major face according to a point of view perpendicular to the first major face.

In this way, the heat disposal capabilities are maximized with equal overall dimensions of the electronic assembly along directions parallel to the major faces of the support plate.

According to another aspect of the invention, the heat sink body may be single, i.e. it may be an individual monolithic body, in particular provided with a single (flat) base face.

According to another aspect of the invention, the heat sink may comprise a base provided with a lowering defining a receiving volume in which at least the support plate is contained and in which the base face is made available by a bottom surface of said lowering.

According to another aspect of the invention, the receiving volume of the lowering can be at least partially filled with a layer of polymeric material that fixes the electronic board to the heat sink body.

In this way, a fast and efficient way of fixing the electronic board to the heat sink body is made available, also considering the fact that in the field of gardening tools the electronic components must already be at least partially incorporated into a polymeric material, generally a resin, for structural reasons.

Still another aspect of the invention provides that the layer of polymeric material can incorporate at least a base portion of the electronic components fixed to the second major face.

According to a further aspect of the invention, the heat sink may comprise a plurality of cooling fins (which develop in a direction opposite to the base face). In this way, heat dispersion is improved.

The invention makes further available a groundskeeping tool comprising an electric motor and an electronic control and command assembly according to claim 1, wherein the electric motor is connected to the electronic control and command board.

The invention also makes available a method for producing a control and command electronic assembly when the heat sink body includes the lowering, this method comprises the steps of:
providing a heat sink body comprising a base equipped with a lowering defining a receiving volume and a base face made available by a bottom surface of said lowering,
providing a control and command electronic board, said control and command electronic board comprising:
   a support plate provided with a first major face and an opposite second major face,
   a plurality of electronic components fixed to the support plate and comprising at least one electronic component fixed to the first major face or to the second major face, which electronic component generates a heat that must be dissipated by means of the heat sink body and has a predetermined height from the major face, between the first and the second, on which it is fixed,
   a connection body, fixed to the support plate and adapted to allow the removable connection to the electronic board of a cable, and/or another electronic component of the plurality of electronic components, which other electronic component is fixed to the support plate and has a predetermined height from a portion of the plate on which it is fixed that is greater than the predetermined height of the electronic component whose heat is to be dissipated, said connection body and/or other electronic component being fixed to the second major face of the support plate
positioning the control and command electronic board inside the lowering with the first major face facing the bottom surface of the lowering and parallel to it,
position the bottom surface of the lowering facing upwards and so that it lies on a horizontal plane,
pour a polymeric material in liquid form, into the recess until it covers at least the second major face of the support plate,
solidify the polymeric material.

According to one aspect of the invention, the polymeric material can be a resin.

According to yet another aspect of the invention, the polymeric layer can cover at least the second major face of the support plate and leave free a portion of the connector distal to the second major face.

### BRIEF DESCRIPTION OF THE DRAWINGS

Further features and advantages of the invention will be more apparent after reading the following description provided by way of non-limiting example, with the aid of the accompanying drawings.

FIG. 1 is a side view of a first and a second embodiment of the electronic control and command assembly according to the invention provided with a heat sink and an electronic board according to the invention.

FIG. 2 is a schematic sectional view of the first embodiment of the electronic control command assembly according to section plane II-II.

FIG. 3 is a schematic sectional view of the second embodiment of the electronic control command assembly according to section plane III-III.

In FIGS. 2 and 3 all the electronic components and the connection bodies are sectioned, however this configuration is purely for illustrative purposes, as it is not necessary for all the components to be aligned along the respective section planes in order to be sectioned as in the proposed figures.

FIG. 4 is an axonometric view of only the heat sink of the electronic control and command assembly according to the invention.

FIG. 5 is a schematic top view of the heat sink of the first embodiment of FIGS. 1 and 2.

FIG. 6 is a schematic top view of the heat sink of the second embodiment of FIGS. 1 and 3.

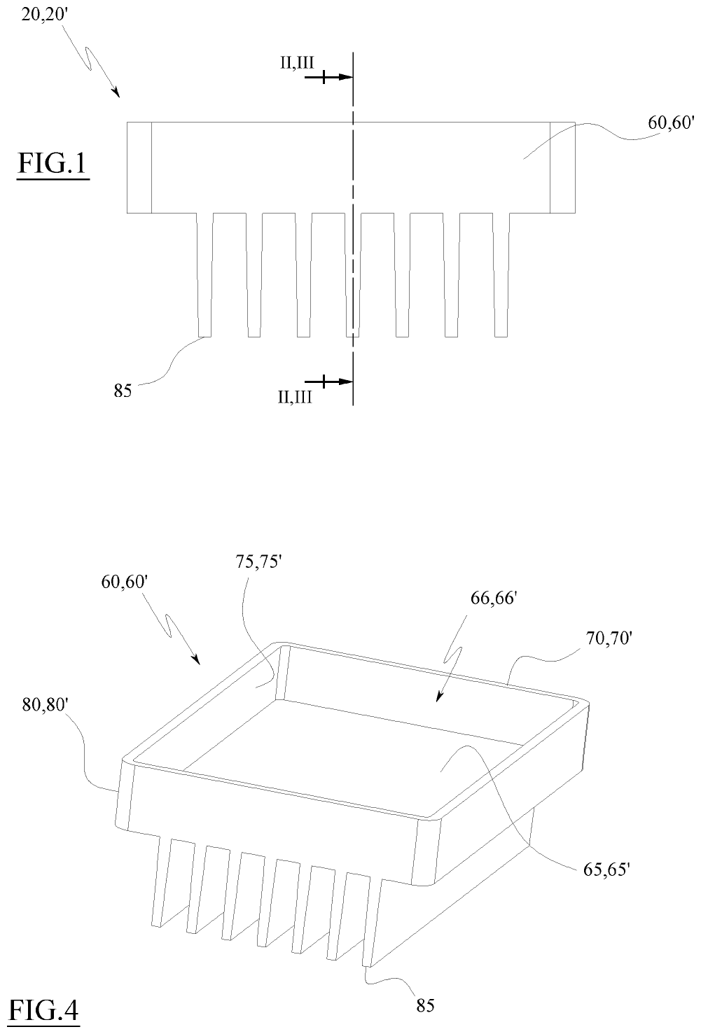

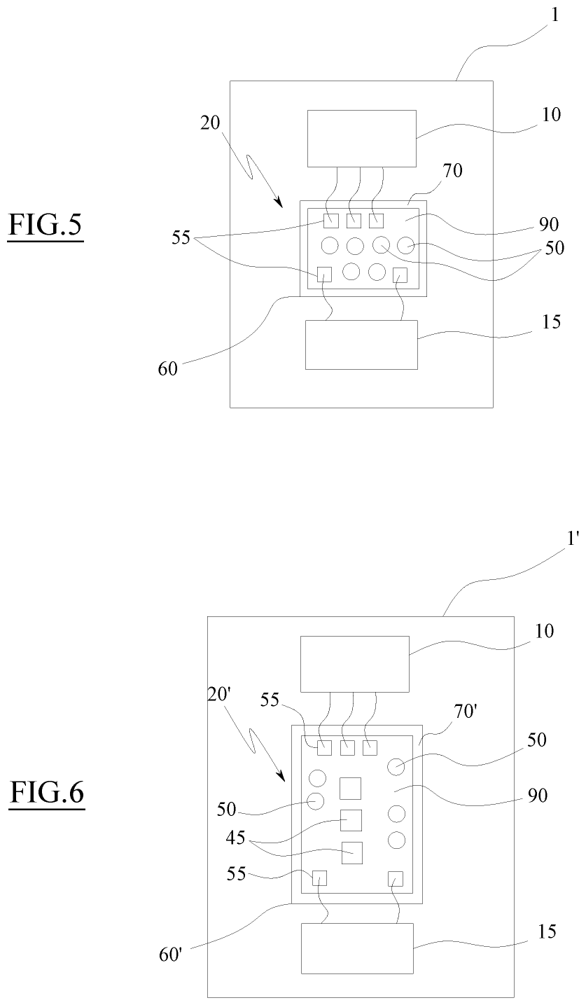

Also for FIGS. 5 and 6, the exact illustrated position of the components is purely for illustrative purposes, as the components may be rearranged differently as long as they fall within the described features of the invention.

### BEST MODE TO IMPLEMENT THE INVENTION

With particular reference to these figures, two embodiments of a groundskeeping tool, such as for example a chainsaw, a brushcutter, a hedge trimmer or a blower, have been indicated with 1 and 1′.

The tool 1,1′ may comprise an electric motor 10, i.e., an electric motor for driving the tool itself. For example, in the case of the chainsaw, brushcutter and hedge trimmer, the electric motor 10 drives a cutting element, whereas in the case of the blower, the electric motor 10 drives an impeller or fan.

The electric motor 10 is powered by an electric power source 15, which may be a battery housed in the tool itself or a cable for the connection to an electric power distribution network.

The groundskeeping tool further comprises an electronic control and command assembly 20,20′, in particular for controlling the electric motor 10, even more in detail for the control and regulation of the electric power supply of the electric motor from the electric power source.

The electronic control and command assembly comprises (i.e. consists of) an electronic control and command board 25,25′ and a heat sink body.

The electronic control and command board 25,25′ comprises a support plate 30,30′ (of non-zero thickness) made at least partially of an electrically insulating material (for example comprising glass fibre) and provided with a first major face 35,35′ (flat) and an opposite (i.e. turned in the opposite direction) second major face 40,40′ (flat), wherein a distance between said two major faces defines the thickness of the plate. For example, the support plate may be substantially rectangular in shape, however any shape suita-ble for the purpose can be used.

The support plate 30,30′ is substantially definable as a printed circuit board, internation-ally known as PCB.

The control and command electronic board 25,25′ comprises a plurality of electronic components fixed to the support plate by means of which the electronic board performs control and command operations.

In particular, the plurality of electronic components comprises at least one electronic component that generates heat (i.e., an amount of heat) that must be dissipated by means of the heat sink body in order to ensure proper operation and durability of the electronic board.

The electronic component that generates the heat to be dissipated by means of the heat sink body can be at least one between a power electronic component and a processor (microchip). The power electronic component can be at least one between a mosfet, a power transistor and a current diverter, for example a mosfet 45 is illustrated in the figures.

In the illustrated embodiments of the invention there are a plurality of components whose heat is to be dissipated by means of the heat sink body, for example a plurality of mosfets 45 are illustrated. It cannot be ruled out that in addition to the power electronic component the processor may be present at the same time, or that the processor may be present in the absence of the power electronic component.

The electronic power component and/or the processor, when fixed to the support plate, has a predetermined maximum height from the support plate itself, i.e. from the major face, between the first and the second on which it is installed. It should be noted that maximum height means the distance, from the major face of the support plate on which it is fixed, of one (top) end of the power electronic component and/or of the processor distal from said major face, i.e. distal (opposite) to a base portion of the electronic power component and/or processor that is fixed to the plate (i.e. to a major face of the plate). The maximum height is also measured along a direction perpendicular to the major face in a portion where the power electronic component and/or the processor is fixed to the corresponding major face.

When a plurality of power electronic components and/or processors are present, the predetermined maximum height refers to the power electronic component or processor having the greatest height from the major face on which they are installed. It is prefera-ble that the components whose heat is to be dissipated all have substantially the same maximum height. Even more preferably, the components whose heat is to be dissipated have (in their end portion distal from the base) a flat surface adapted to be contacted by the dissipator.

For example, in the illustrated embodiments there are a plurality of mosfets of equal height, each of which also has a flat surface in their flat portion, all lying on the same plane (parallel to the first major face).

The plurality of electronic components may also comprise another electronic component (not a power component and not a processor) that does not require heat dissipation by the heat sink body, for example a plurality of other electronic components that do not require heat dissipation by the heat sink body. Further, said other electronic component preferably has a predetermined maximum height from a major face of the flat plate on which they are installed that is greater than the predetermined maximum height of the power electronic component and/or the processor. However, it is not excluded that in an embodiment not illustrated, the predetermined maximum height of the other electronic component may be equal to or less than the maximum height of the power electronic component and/or processor.

The aforementioned other electronic component may for example be a capacitor 50, i.e. a plurality of capacitors 50. As can also be seen from the figures, the capacitor has a maximum height (with respect to the installation face on the support plate) greater than the mosfet 45, i.e. the capacitors all have a maximum height greater than the plurality of mosfets 45.

The plurality of electronic components is then divided into the two delineated sets, i.e. the set of those requiring heat dissipation by means of the heat sink body and those not (and which also have a height from the support plate that is greater than of those requiring heat dissipation due to the heat sink body).

As an alternative or in addition to the other electronic component (the one that does not require heat dissipation made available by the heat sink body), the electronic board 25,25′ comprises at least one connection body, preferably a plurality of connection bodies, configured to allow a removable (galvanic) connection to the electronic board of cables (data cables and/or power cables) external to the board for connection to other components of the tool, such as for example for connecting to the battery and to the tool motor.

The connection body, i.e. each connection body, is galvanically connected to at least one electronic component of the plurality of electronic components, for example at least to the power electronic component and/or processor.

The connection body, i.e. each connection body, may for example be a connector or a terminal, preferably it is a connector 55.

It is specified that connector means a portion fixed to the support plate of a plug-n-play coupling, i.e. a coupling that allows a cable to be fixed to the support plate without the need for tools. In detail, the connector 55 can comprise a guide body fixed to a major face of the support plate (in particular the second, as will be clearer below) and which rises therefrom defining a guide for a complementary coupling body fixed to an end of the cable to be connected.

The connector further comprises electrical contacts for connection with the cable to be connected, in particular forming a galvanic connection with other electrical contacts present in the cable coupling body.

A terminal, that is an electrical terminal, on the other hand, refers to a body that allows the removable connection of a cable whose end is bare (i.e. without an insulating coating and in which the copper wires are visible). In particular, the terminal is provided with a mechanism for mechanically and reversibly fixing said bare end of the cable, for example comprising a screw.

In the illustrated embodiments, both the connection bodies and the other electronic components that do not generate a heat to be dissipated with the heat sink body are present, however it is not excluded that in alternative embodiments not illustrated there may be either the connection body without the other electronic component, of which there is no need to dissipate the heat with the heat sink body, or the other electronic component, of which there is no need to dissipate the heat without the connection body. In particular, in the latter case, the cables connecting the electronic board to the other components of the tool, such as for example the motor and the battery, could be welded to the support plate (in particular to the second major face of the support plate, for the same reasons set out in the exposition of the invention and which will also be discussed below).

As indicated above, the electronic control and command assembly 1,1′ also comprises a (single and monolithic) heat sink body 60,60′, which is made of a material having a high thermal conduction capacity, such as for example copper or aluminium.

The heat sink body comprises a base portion turned towards the electronic control and command board 25,25′, in particular the base portion and the first major face 35,35′ are turned to each other.

The heat sink body comprises a base face (or surface) 65,65′ (obviously made of themally conductive material) facing (only) the first major face of the support plate and parallel to it. For example, the base face 65,65′ is entirely flat. It should be noted that in in-dicating that the base face can only be facing onto the first major face of the support plate, it is understood that it is turned towards the first major face and that the first major face and the base face are turned to each other. Furthermore, this implies that no portion of the base face is facing onto the major face. Additionally, no portion of the heat sink body is simultaneously turned on the second major face and substantially parallel to it.

The base face 65,65′ is provided with at least one portion in contact with a portion of the electronic control and command board. Such contact may be direct or mediated by a thermally conductive layer (e.g., a conductive paste layer).

The base face 65,65′ is for example totally superimposed on the first major face (and on the second major face) according to a point of view perpendicular to the first major face. In particular, it has the same shape as the first major face and an area (measured along a plane parallel to the first major face) at least equal to or greater than an area of the first major face.

The base of the heat sink body comprises a (single) lowering, e.g. in the form of a basin or cup, which defines a housing volume 66,66′ of at least part of the electronic control and command board.

Said lowering is provided with a bottom (flat) surface, which makes available the base face 65,65′ (i.e. which coincides with the base face), and a perimeter side wall 70,70′ (orthogonal to the bottom surface) which rises from a perimeter edge of the surface along a closed loop path around the bottom surface itself.

A top portion, i.e. a portion distal from the bottom surface, of the perimeter side wall 70,70′ defines an opening of the lowering for access to the inside of the receiving volume (therefore for the insertion of the electronic control and command board). The bottom surface is for example rectangular in shape and the perimeter side wall fol-lows the perimeter of the rectangle thus comprising two major straight side walls that are opposite to each other and two minor straight side walls, opposite to each other and orthogonal to the major side walls.

This side part is, for example, seamlessly continuous along the entire perimeter of the base face 65,65′, just as the bottom surface is seamlessly continuous. In practice, the lowering is shaped in such a way that it can hold a liquid in its inside when it is oriented with the bottom surface turned upwards.

The depth of the lowering is such that at least the support plate of the electronic board arranged with the first major face parallel to the bottom surface, can be completely contained within it. Preferably, the second major face of the support plate is also entirely contained within the receiving volume of the lowering. In particular, the second major face has a distance from the bottom surface that is less than a distance from the bottom surface of the top portion of the perimeter side wall.

It should be noted that the depth of the lowering is substantially the distance between the bottom surface and the top portion of the perimeter side wall.

The depth of the lowering is much less than its width and length (measured along a plane parallel to the bottom surface). For example, it is less than one third of the larger of the width and length.

The perimeter side wall 70,70′ comprises an inner annular surface 75,75′ turned towards the housing volume and an opposite outer annular surface 80,80′ turned in the direction opposite to the inner annular surface, such that the distance between said two surfaces defines a thickness of the perimeter side wall. In particular, the wall is thin, i.e. the height of the perimeter side wall from the bottom surface is at least twice the thickness of the perimeter side wall itself.

The outer annular surface of the perimeter side wall also defines the maximum overall dimensions of the heat sink body (and also of the entire electronic control and command assembly) along a plane parallel to or lying on the bottom surface. In other words, no other element of the heat sink body (and also of the entire electronic control and command assembly) protrudes beyond the outer annular surface 80,80′ along a plane parallel to the bottom surface.

The inner annular wall comprises four flat surfaces two by two parallel to each other facing inwardly of the receiving volume and of which one pair of parallel surfaces is perpendicular to the other pair of parallel flat surfaces. The outer annular wall is shaped in the same way, except for the fact that the surfaces are turned in the opposite direction with respect to the inside of the receiving volume.

The heat sink body also comprises a plurality of cooling fins 85 which develop from the base of the heat sink body extending in the direction opposite to the circuit printed board.

The heat sink body and/or the electronic board may comprise threaded holes for fixing the electronic control and command assembly to a frame or to a casing of the groundskeeping tool.

The electronic board is maintained in the lowering of the base (only) by a layer (a casting) of polymeric material 90, for example a resin, which at least partially fills the housing volume by fixing (in a non-removable way, i.e. substantially by gluing) the electronic board to the heat sink body.

This layer of polymeric material 90 extends from the bottom surface (which it contacts and to which it is glued) until it covers at least the second major face of the support board. In particular, as will be clear below, the layer of polymeric material incorporates a base portion fixed to the second major face of the electronic components fixed to the second major face.

In particular, of the electronic components fixed to the second major face, it only incorporates a respective base portion.

The connector, as visible in the figures, protrudes at least partially from the layer of polymeric material. In other words, at least a portion of the connector distal from the second major face is not incorporated in the layer of polymeric material.

The layer of polymeric material also extends as far as it touches (and is glued to) the perimeter side wall of the lowering.

The invention makes therefore available a method for the production of the electronic control and command assembly that provides for making available the heat sink body provided with the lowering in the form of a basin or cup, positioning the electronic board in its inside with the first major face turned towards the bottom surface of the lowering and parallel to it, positioning the bottom surface turned upwards and so that it lies on a horizontal plane, pouring a polymeric material in liquid form (for example resin) into the lowering until at least the second major face of the support plate is covered.

Furthermore, the layer of polymeric material does not have to completely cover the connector, so that it is possible to use it. In particular, the polymeric layer covers at least the second major face of the support plate and leaves free, or does not cover, a portion of the connector distal to the second major face. Subsequently, the solidification of the polymeric material is waited for or artificially accelerated.

Once the polymeric material has been solidified, the electronic board is fixed to the heat sink body.

In detail, the method is the following.

Method for producing a control and command electronic assembly 1,1′ comprising the steps of:
providing the heat sink body 60,60′ comprising a base equipped with the lowering defining the receiving volume 66,66′ and the base face 65,65′ made available by a bottom surface of said lowering,
providing the control and command electronic board 25,25′, said control and command electronic board comprising:
   the support plate 30,30′ provided with the first major face 35,35′ and the opposite second major face 40,40′,
   the plurality of electronic components 45,50 fixed to the support plate and comprising at least the electronic component 45 fixed to the first major face or to the second major face, which electronic component generates a heat that must be dissipated by means of the heat sink body and has a predetermined height from the major face, between the first and the second, on which it is fixed,
   the connection body 55, fixed to the support plate 30,30′ and adapted to allow the removable connection to the electronic board of a cable, and/or the another electronic component 50 of the plurality of electronic components, which other electronic component is fixed to the support plate and has a predetermined height from a portion of the support plate 30,30′ on which it is fixed that is greater than the predetermined height of the electronic component whose heat is to be dissipated, said connection body 55 and/or the other electronic component being fixed to the second major face 40,40′ of the support plate
positioning the control and command electronic board inside the lowering with the first major face 35,35′ facing the bottom surface of the lowering and parallel to it,
position the bottom surface of the lowering facing upwards and so that it lies on a horizontal plane,
pour a polymeric material in liquid form, into the recess until it covers at least the second major face of the support plate,
solidify the polymeric material, which for example can be a resin.

The step of pouring the polymeric material can comprise the step of covering at least the second major face of the support plate and leaving free a portion of the connector distal to the second major face.

Further, the invention makes available two embodiments of the electronic control and command board, and thus of the electronic control and command assembly, which differ in the positioning of the electronic components on the support plate, but which have in common that the connection body, for example the connector 55, and/or the other electronic component of the plurality of electronic components, for example the capacitor 50, is (or are if both) fixed to the second major face of the support plate and for example it rises therefrom (only, i.e. it does not cross the support plate) in a direction away from the first major face, i.e. in a direction away from the base face of the heat sink body. As already explained in the exposition of the invention, thanks to this solution, an electronic control and command assembly is made available, which makes it possible to have either, with the same size of the support plate, heat sinks with larger bases and therefore a greater dissipation capacity, or which, with the same size of the base of the heat sink body, makes it possible to obtain electronic boards that are more compact compared to the devices of prior art from the point of view of the extension of the major faces of the support plate. In the embodiment illustrated, both a plurality of capacitors and a plurality of connectors are installed on the second major face.

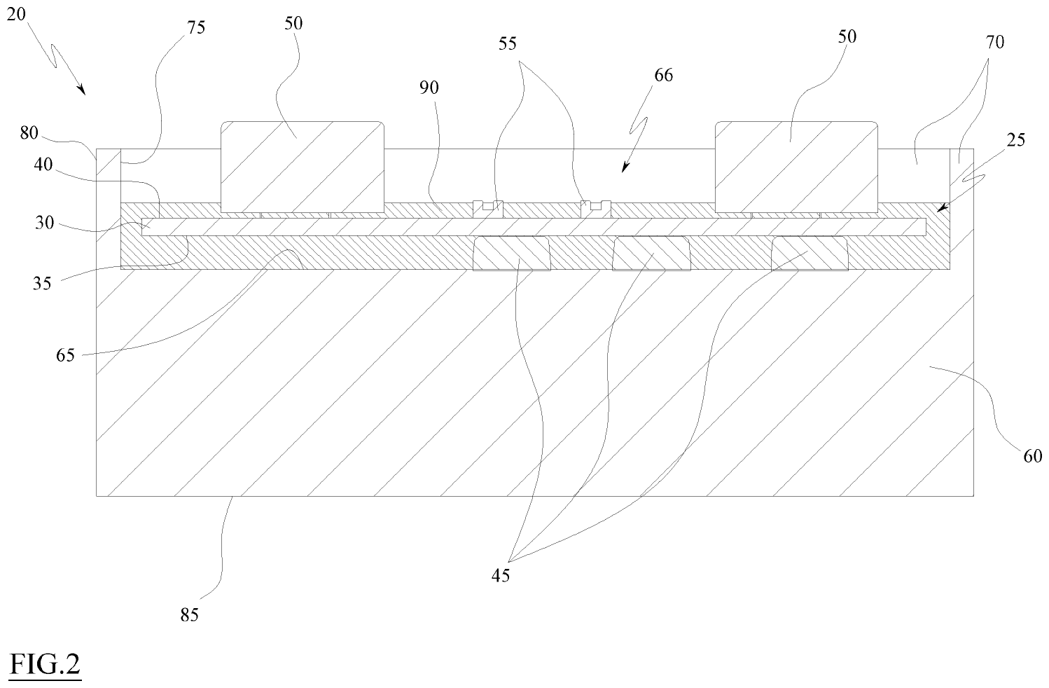

In the embodiment 1 of the electronic control and command assembly of FIGS. 2 and 5, the electronic component whose heat is to be dissipated with the heat sink body is fixed to the first major face of the support plate and rises therefrom towards the heat sink body by contacting (directly, or by means of a layer of conductive material) the base face, i.e. the bottom surface, of the heat sink body.

In particular, in this embodiment the mosfet 45, i.e., the plurality of mosfets 45, is fixed to the first major face of the support plate and contacts the base face, i.e., the bottom surface, of the heat sink body.

Although in FIGS. 2 and 5 only the mosfets fixed to the first major face are illustrated, it is not excluded that in alternative embodiments not illustrated there may be other components fixed to the first major face, for example for which heat dissipation due to the heat sink body is not important. In this case, all the electronic components fixed to the first major face have a maximum height from the first major face itself lower than the predetermined maximum height from the first face of the power electronic component and/or processor in contact with the base face of the heat sink. For example, all the electronic components having a maximum height equal to or less than the predetermined maximum height of the power electronic component or of the processor are fixed to the first major face and all the electronic components having a maximum height greater than the predetermined maximum height of the power electronic component or of the processor, and the connection bodies, are fixed to the second major face.

In other words, the base face, i.e. the bottom surface, of the heat sink body is placed at a predetermined distance from the first major face (in addition to being facing onto it and parallel to it) and all the electronic components having a maximum height equal to or less than the predetermined distance are fixed to the first major face, while all the electronic components having a maximum height greater than the predetermined distance and the connection bodies are fixed to the second major face.

Additionally, the predetermined distance substantially corresponds to the predetermined maximum height of the power electronic component and/or processor.

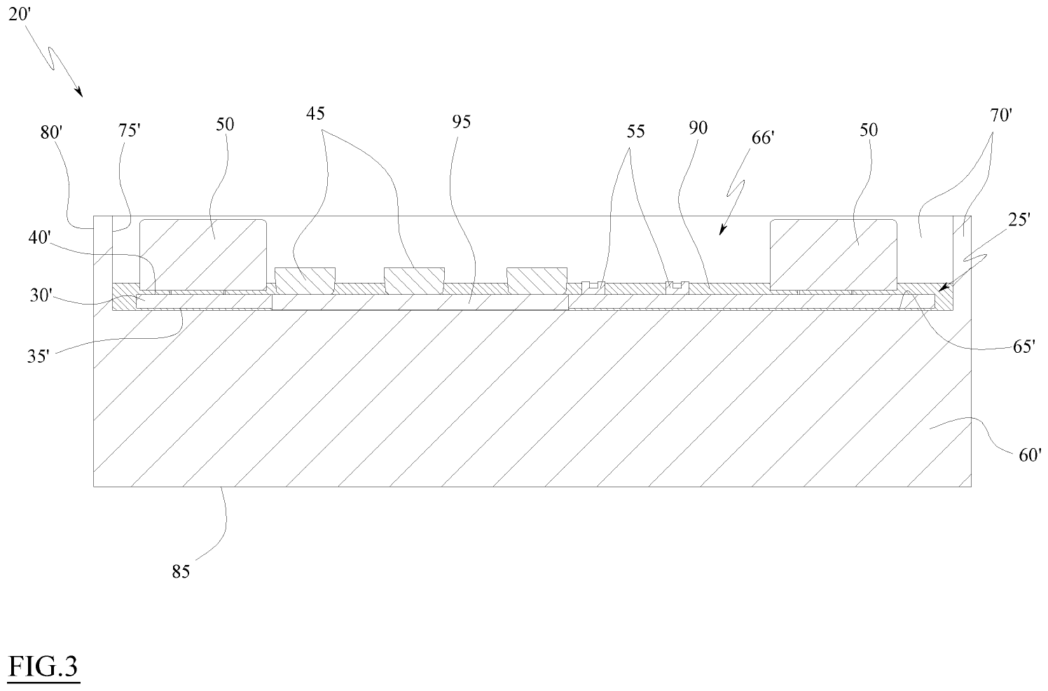

In the embodiment 1′ of the electronic control and command assembly of FIGS. 3 and 6, all the electronic components of the plurality of electronic components, therefore both the power electronic component (or the processor), i.e. those whose heat needs to be dissipated, and the other electronic component and/or the connection body are installed on the second major face.

In particular, in the embodiment illustrated, the capacitor, i.e. the capacitors, the mosfet, i.e. the mosfets, and the connector, i.e. the connectors, are installed on the second major face.

In this embodiment, the electronic board comprises a thermally conductive bridge 95 that crosses the support plate from the second major face (included) to the first major face (included) and is in contact (direct or by means of a layer of thermally conductive material, such as for example a thermally conductive paste) with the base face, i.e. with the bottom surface of the heat sink body, so as to create a thermal bridge through the support plate at least between the components of which the heat is to be dissipated and the heat sink body.

In particular, the thermally conductive bridge 95 protrudes, for example by a few thou-sandths of a millimetre, from the first major face so as to ensure proper contact with the base face.

The thermally conductive bridge is shaped like a flat plate inserted into the support plate (thus it is partially incorporated into the electrically insulating material of the support plate).

Regardless of the exact shape, the thermal bridge has a flat surface in contact with the heat sink body.

In an alternative embodiment not illustrated, a plurality of thermally conductive bridges may be envisaged.

The invention thus conceived is susceptible to several modifications and variations, all falling within the scope of the inventive concept.

Moreover, all details can be replaced by other technically equivalent elements. In practice, the materials used, as well as the contingent shapes and sizes, can be whatever according to the requirements without for this reason departing from the scope of protection of the following claims.

1. An electronic control and command electronic assembly for a groundskeeping tool, said control and command electronic assembly comprising a heat sink body and a control and command electronic board, said electronic board comprising:
a support plate provided with a first major face and an opposite second major face,
a plurality of electronic components fixed to the support plate (30,30′) and comprising at least one electronic component fixed to the first major face or to the second major face, which electronic component generates a heat that must be dissipated by means of the heat sink body and has a predetermined height from the major face, between the first and the second, on which it is fixed,
a connection body, fixed to the support plate and adapted to allow the removable connection to the electronic board of a cable, and/or another electronic component of the plurality of electronic components, which other electronic component is fixed to the support plate and has a predetermined height from a portion of the plate on which it is fixed that is greater than the predetermined height of the electronic component whose heat is to be dissipated,
said electronic assembly being characterized in that the heat sink body comprises a base face facing onto the first major face of the support plate and in that the connection body and/or the other electronic component is fixed to the second major face of the support plate.

2. The electronic control and command assembly according to claim 1, wherein the electronic component whose heat is to be dissipated with the heat sink body is fixed to the first major face and is in contact with the base face of the heat sink body.

3. The electronic control and command assembly according to claim 2, wherein the plurality of electronic components comprises only:
a first set of electronic components, fixed to the first major face, of which the electronic component whose heat is to be dissipated is a part, and all of which have a height from the first major face of the support plate equal to or less than the predetermined height of the electronic component in contact with the base face and whose heat is to be dissipated, and
a second set of electronic components fixed to the second major face of the support plate, all of which have a height from the second major face of the support plate greater than the predetermined height of the electronic component in contact with the base face of the heat sink body.

4. The electronic control and command assembly according to claim 1, wherein all the electronic components of the plurality of electronic components are installed on the second major face of the support plate and the electronic board comprises one or more bridges of thermally conductive material that cross the support plate from the second major face to the first major face and are in contact with the base face of the heat sink body.

5. The electronic control and command group according to claim 1, wherein the base face of the heat sink body is totally superimposed on the first major face according to a point of view perpendicular to the first major face itself.

6. The electronic control and command assembly according to claim 1, wherein the heat sink body is single.

7. The electronic control and command assembly according to claim 1, wherein the heat sink body comprises a base provided with a lowering defining a receiving volume in which at least the support plate is contained and in which the base face is made available by a bottom surface of said lowering.

8. The electronic control and command assembly according to claim 7, wherein the receiving volume of the lowering is at least partially filled with a layer of polymeric material (90) that fixes the electronic control and command board to the heat sink body.

9. The electronic control and command assembly according to claim 8, wherein the layer of polymeric material includes at least a base portion of the electronic components fixed to the second major face.

10. A groundskeeping tool comprising an electric motor and an electronic control and command assembly according to claim 1, wherein the electric motor is connected to the electronic control and command board.
